(19) United States
(12) Patent Application Publication
(10) Pub. No.: US 2024/0389392 A1
(43) Pub. Date: Nov. 21, 2024

(54) DISPLAY SUBSTRATE, MANUFACTURING METHOD THEREOF, AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Wei Zhang, Beijing (CN); Xiangdan Dong, Beijing (CN); Xiaoliang Guo, Beijing (CN); Zhao Guo, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/268,546

(22) PCT Filed: Aug. 1, 2022
(86) PCT No.: PCT/CN2022/109364

§ 371 Date: Jun. 20, 2023

(51) Int. Cl. H10K 59/122; H10K 59/00; H10K 59/12; H10K 59/80

(52) U.S. Cl. CPC H10K 59/122; H10K 59/1201; H10K 59/771; H10K 59/80517

(57) ABSTRACT

A display substrate and a manufacturing method thereof, and a display device relate to the technical field of displaying. The display substrate includes a base substrate; a pixel defining layer arranged at one side of the base substrate, the pixel defining layer is configured for defining a plurality of opening areas, and the opening area is configured for arranging a light emitting device; and a common transport layer arranged at one side of the pixel defining layer away from the base substrate; a surface of one side away from the base substrate of the pixel defining layer between at least two adjacent opening areas is covered by the common transport layer, and at least part of a side face of the pixel defining layer facing at least one opening area is not covered by the common transport layer.

### TECHNICAL FIELD

The present disclosure relates to the technical field of displaying and, more particularly, to a display substrate and a manufacturing method thereof, and a display device.

### BACKGROUND

An organic light emitting diode (OLED) is an active light emitting display device, which has the advantages of self-luminescence, wide viewing angle, high contrast, low power consumption, wide color gamut, thinness and ability of being irregular-shaped.

### SUMMARY

The present disclosure provides a display substrate, including:
a base substrate;
a pixel defining layer arranged at one side of the base substrate, the pixel defining layer being configured for defining a plurality of opening areas, and the opening area being configured for arranging a light emitting device; and
a common transport layer arranged at one side of the pixel defining layer away from the base substrate;
wherein a surface of one side away from the base substrate of the pixel defining layer between at least two adjacent opening areas is covered by the common transport layer, and at least part of a side face of the pixel defining layer facing at least one opening area is not covered by the common transport layer; and
orthographic projections of the common transport layers in the at least two adjacent opening areas on the base substrate and orthographic projections of the common transport layers on the pixel defining layers between the at least two adjacent opening areas on the base substrate are continuous.

In an optional embodiment, the pixel defining layer includes a partition structure, and the partition structure includes:
a partition groove arranged in a side face of the pixel defining layer facing the at least one opening area, and a notch of the partition groove facing the at least one opening area.

In an optional embodiment, the display substrate further includes:
a bottom electrode layer and a partition layer arranged in layer configuration between the base substrate and the pixel defining layer, wherein the bottom electrode layer is located between the base substrate and the partition layer;
wherein an orthographic projection of the partition layer on the base substrate is located within an orthographic projection range of the pixel defining layer on the base substrate; and the partition layer is provided with a first end face facing the opening area, the pixel defining layer located at one side of the partition layer away from the base substrate is provided with a second end face facing the opening area, the first end face retracts in a direction away from the opening area relative to the second end face, and the first end face forms a groove bottom of the partition groove.

In an optional embodiment, the display substrate includes a first active area; in the first active area, the bottom electrode layer includes a first bottom electrode, the plurality of opening areas include a first opening area, and the partition layer includes a first partition part; and an orthographic projection of the first bottom electrode on the base substrate covers an orthographic projection of the first opening area on the base substrate, and the first partition part and the first bottom electrode are contacted with each other; and
the display substrate further includes: a thin film transistor layer and an insulating layer arranged in layer configuration between the base substrate and the bottom electrode layer, wherein the thin film transistor layer is located between the base substrate and the insulating layer; and the thin film transistor layer includes: a first thin film transistor and a first switching part connected to a source electrode or a drain electrode of the first thin film transistor;
wherein orthographic projections of the first bottom electrode and the first switching part on the base substrate do not intersect or overlap; and orthographic projections of the first partition part and the first switching part on the base substrate intersect or overlap, and the first bottom electrode and the first switching part are connected through a via hole arranged on the insulating layer.

In an optional embodiment, the first active area is located within a transparent active area, the bottom electrode layer includes a metallic material, and the partition layer includes a transparent conducting material.

In an optional embodiment, the display substrate includes a second active area; in the second active area, the bottom electrode layer includes a second bottom electrode, and the plurality of opening areas include a second opening area; and an orthographic projection of the second bottom electrode on the base substrate covers an orthographic projection of the second opening area on the base substrate; and
the display substrate further includes: a thin film transistor layer and an insulating layer arranged in layer configuration between the base substrate and the bottom electrode layer, wherein the thin film transistor layer is located between the base substrate and the insulating layer; and the thin film transistor layer includes: a second thin film transistor and a second switching part connected to a source electrode or a drain electrode of the second thin film transistor;
wherein orthographic projections of the second bottom electrode and the second switching part on the base substrate intersect or overlap, and the second bottom electrode and the second switching part are connected through a via hole arranged on the insulating layer.

In an optional embodiment, a surface material of one side of the bottom electrode layer away from the base substrate includes at least one of the following: a crystalline metallic oxide, an amorphous metallic oxide, a metal and residual particles of the partition layer; and/or
a material of the partition layer includes at least one of the following: an amorphous metallic oxide, a metal, silicon oxide, silicon nitride and silicon oxynitride; and/or
a main material of the pixel defining layer is an organic material.

In an optional embodiment, the display substrate further includes: a composite electrode layer arranged between the base substrate and the pixel defining layer;
wherein the composite electrode layer includes a plurality of composite electrodes, the composite electrode includes a middle pattern and an edge pattern surrounding the middle pattern, orthographic projections of the middle pattern and the pixel defining layer on the base substrate do not intersect or overlap, and orthographic projections of at least part of the edge pattern and the pixel defining layer on the base substrate intersect or overlap; and
the middle pattern and the edge pattern at least include a material with the same element but different structures, and the middle pattern and the edge pattern are at least partially located on a same surface of a same layer.

In an optional embodiment, the pixel defining layer includes:
a first material layer and a second material layer which are arranged in layer configuration, wherein the first material layer is located between the base substrate and the second material layer;
wherein the first material layer is provided with a third end face facing the opening area, the second material layer is provided with a fourth end face facing the opening area, the third end face retracts in a direction away from the opening area relative to the fourth end face, and the third end face forms a groove bottom of the partition groove.

In an optional embodiment, the pixel defining layer further includes:
a third material layer arranged between the first material layer and the base substrate, and the third material layer being provided with a fifth end face facing the opening area; wherein the third end face further retracts in a direction away from the opening area relative to the fifth end face.

In an optional embodiment, a main material of the pixel defining layer is an inorganic material.

In an optional embodiment, the inorganic material includes at least one of the following: silicon oxide, silicon nitride, silicon oxynitride and metal.

In an optional embodiment, the display substrate further includes:
a filling layer arranged between the pixel defining layer and the common transport layer, wherein an orthographic projection of the filling layer on the base substrate and an orthographic projection of the partition groove on the base substrate intersect or overlap, and the filling layer is configured for filling the partition groove at a corresponding position.

In an optional embodiment, a groove depth of the partition groove is greater than or equal to 0.1 micron, and less than or equal to 10 microns in a plane at which the base substrate is located.

In an optional embodiment, a dimension of the partition groove is greater than or equal to 100 angstroms, and less than or equal to 10,000 angstroms in a normal direction of the base substrate.

In an optional embodiment, the partition groove is a closed structure or a non-closed structure surrounding the opening area by one circle.

In an optional embodiment, the common transport layer includes at least one of the following: a hole injection layer, a hole transport layer, a charge generating layer, a light emitting layer, an electron transport layer and an electron injection layer which are arranged in layer configuration.

In an optional embodiment, the display substrate further includes:
a top electrode layer arranged at one side of the common transport layer away from the base substrate;
wherein the top electrode layer in the at least two adjacent opening areas and the top electrode layer on the pixel defining layer between the at least adjacent two opening areas are at least partially lapped.

The present disclosure provides a display device, including the display substrate according to any one of embodiments stated above.

The present disclosure provides a manufacturing method of a display substrate, including:
providing a base substrate;
forming a pixel defining layer at one side of the base substrate, the pixel defining layer being configured for defining a plurality of opening areas, and the opening area being configured for arranging a light emitting device; and
forming a common transport layer at one side of the pixel defining layer away from the base substrate;
wherein a surface of one side away from the base substrate of the pixel defining layer between at least two adjacent opening areas is covered by the common transport layer, and at least part of a side face of the pixel defining layer facing at least one opening area is not covered by the common transport layer; and
orthographic projections of the common transport layers in the at least two adjacent opening areas on the base substrate and orthographic projections of the common transport layers on the pixel defining layers between the at least two adjacent opening areas on the base substrate are continuous.

In an optional embodiment, the pixel defining layer includes a partition structure, the partition structure includes a partition groove arranged in a side face of the pixel defining layer facing the opening area, and the step of forming the pixel defining layer at one side of the base substrate includes:
forming a bottom electrode layer at one side of the base substrate, the bottom electrode layer including a plurality of bottom electrodes, and orthographic projections of the plurality of bottom electrodes on the base substrate covering orthographic projections of the plurality of opening areas on the base substrate;
forming a partition material layer at one side of the bottom electrode layer away from the base substrate by patterning, an orthographic projection of the partition material layer on the base substrate covering the orthographic projections of the plurality of bottom electrodes on the base substrate;
forming the pixel defining layer at one side of the partition material layer away from the base substrate; and
etching the partition material layer located in the opening area to form a partition layer; wherein an orthographic projection of the partition layer on the base substrate is located within an orthographic projection range of the pixel defining layer on the base substrate; and the partition layer is provided with a first end face facing the opening area, the pixel defining layer located at one side of the partition layer away from the base substrate is provided with a second end face facing the opening area, the first end face retracts in a direction away from the opening area relative to the second end face, and the first end face forms a groove bottom of the partition groove.

The above description is merely a summary of the technical solutions of the present disclosure. In order to more clearly know the elements of the present disclosure to enable the implementation according to the contents of the description, and in order to make the above and other purposes, features and advantages of the present disclosure more apparent and understandable, the particular embodiments of the present disclosure are provided below.

### BRIEF DESCRIPTION OF THE DRAWINGS

In order to more clearly illustrate the technical solutions of the embodiments of the present disclosure or the prior art, the figures that are required to describe the embodiments or the prior art may be briefly introduced below. Apparently, the figures that are described below are embodiments of the present disclosure, and a person skilled in the art can obtain other figures according to these figures without paying creative work. It should be noted that the proportions in the drawings are only indicative and do not represent actual proportions.

FIG. 1 schematically shows a schematic diagram of a structure of a plane of a first display substrate provided by the present disclosure;

FIG. 2a schematically shows a schematic sectional structural diagram of first and second display substrates provided by the present disclosure in a first position;

FIG. 2b schematically shows a schematic sectional structural diagram of the first and second display substrates provided by the present disclosure in the first position;

FIG. 3 schematically shows a schematic sectional structural diagram of a light emitting device;

FIG. 4 schematically shows a schematic diagram of a structure of a plane of a second display substrate provided by the present disclosure;

FIG. 5 schematically shows a schematic diagram of a structure of a plane of one sub-pixel in a first active area;

FIG. 6 schematically shows a schematic diagram of a structure of a plane of one sub-pixel in a second active area;

FIG. 7 schematically shows a schematic sectional structural diagram of a third display substrate provided by the present disclosure;

FIG. 8 schematically shows a schematic sectional structural diagram of a fourth display substrate provided by the present disclosure;

FIG. 9 schematically shows a schematic sectional structural diagram of the first and second display substrates provided by the present disclosure in a second position;

FIG. 10 schematically shows a schematic diagram of a structure of a plane of a display substrate provided by the present disclosure in a manufacturing process; and

FIG. 11 schematically shows a schematic sectional structural diagram of a display substrate provided by the present disclosure in a manufacturing process.

### DETAILED DESCRIPTION

In order to make purposes, technical schemes and advantages of embodiments of this disclosure more clearer, the technical schemes in the embodiments of this disclosure will be described clearly and completely with reference to the drawings in the embodiments of this disclosure; and it is obvious that the described embodiments are part of the embodiments of this disclosure, but not all of them. On a basis of the embodiments in this disclosure, all other embodiments obtained by the ordinary skilled in the art without paying creative effort are within a protection scope of this disclosure.

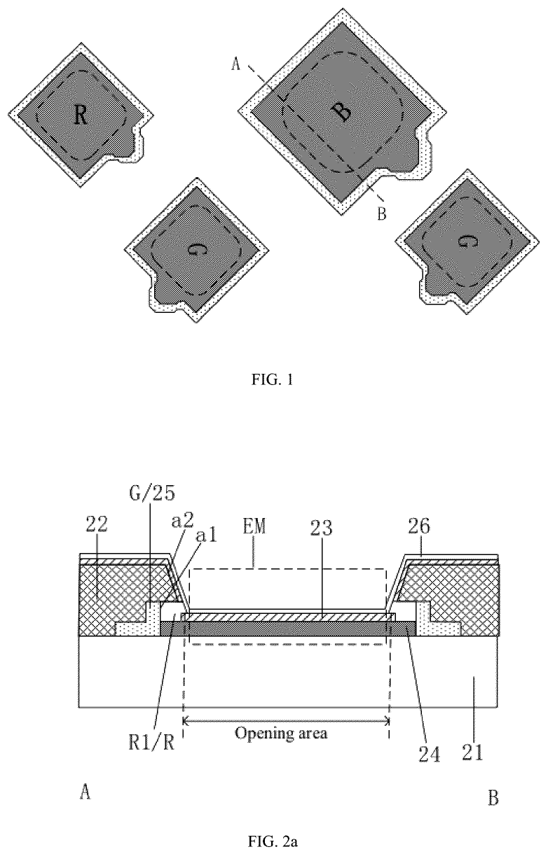

The present disclosure provides a display substrate. Referring to FIG. 1 and FIG. 4, FIG. 1 and FIG. 4 schematically show schematic diagrams of planes of structures of a display substrate provided by the present disclosure respectively. As shown in FIG. 1 or 4, the display substrate may include a plurality of sub-pixels. The plurality of sub-pixels include a red sub-pixel R, a green sub-pixel G, a blue sub-pixel B, and the like.

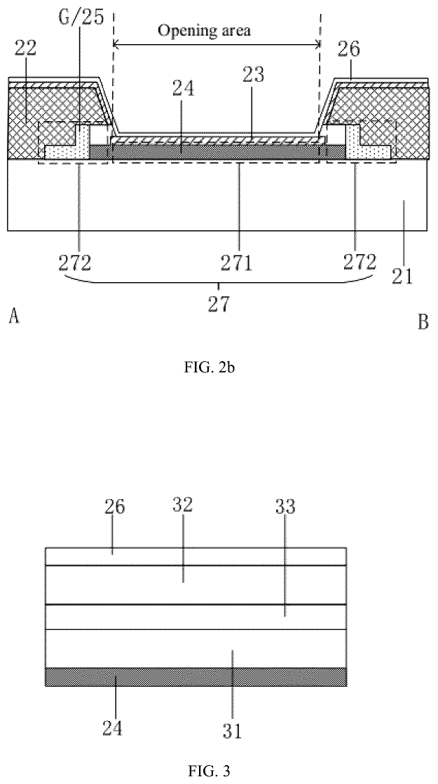

Referring to FIG. 2a, FIG. 2a schematically shows schematic sectional structural diagrams of the display substrates shown in FIG. 1 and FIG. 4 along a dotted line AB. As shown in FIG. 2a, the display substrate includes: a base substrate 21; a pixel defining layer 22 arranged at one side of the base substrate 21, the pixel defining layer 22 being configured for defining a plurality of opening areas; and a common transport layer 23 arranged at one side of the pixel defining layer 22 away from the base substrate 21.

A surface of one side away from the base substrate 21 of the pixel defining layer 22 between at least two adjacent opening areas is covered by the common transport layer 23, and at least part of a side face of the pixel defining layer 22 facing at least one opening area is not covered by the common transport layer 23. Moreover, orthographic projections of the common transport layers 23 in the at least two adjacent opening areas on the base substrate 21 and orthographic projections of the common transport layers 23 on the pixel defining layers 22 between at least two adjacent opening areas on the base substrate 21 are continuous.

As shown in FIG. 2a, the surface of one side of the pixel defining layer 22 away from the base substrate 21 is an upper surface of the pixel defining layer 22. The surface of one side of the pixel defining layer 22 away from the base substrate 21 is adjacent to a side face of the pixel defining layer 22 facing the opening area.

As shown in FIG. 2a, the common transport layer 23 located on at least part of the side face of the pixel defining layer 22 facing at least one opening area is disconnected in a normal direction of the base substrate 21, but the orthographic projection of the common transport layer 23 located on at least part of the side face of the pixel defining layer 22 facing at least one opening area on the base substrate 21 is continuous.

Since at least part of the side face of the pixel defining layer 22 facing at least one opening area is not covered by the common transport layer 23, that is, the common transport layer 23 is at least partially disconnected at the side face of the pixel defining layer 22, carrier transport in the common transport layer 23 between two adjacent opening areas can be reduced, so that a signal crosstalk problem between different sub-pixels can be improved and a display effect is improved.

Optionally, as shown in FIG. 2a, the pixel defining layer 22 includes a partition structure R. The partition structure R is arranged on the side face of the pixel defining layer 22 facing at least one opening area, and the partition structure R can partition the common transport layer 23 at a corresponding position, so that at least part of the side face of the pixel defining layer 22 facing at least one opening area is not covered by the common transport layer 23.

The common transport layer 23 in the present disclosure may be a continuous film layer covering other parts of the pixel defining layer 22 and the plurality of opening areas except the position corresponding to the partition structure R.

Optionally, as shown in FIG. 2a, the partition structure R may include: a partition groove R1 arranged in the side face of the pixel defining layer facing at least one opening area, and a notch of the partition groove R1 faces at least one opening area.

As shown in FIG. 2a, since the partition groove R1 is located in the side face of the pixel defining layer 22, in a subsequent process of forming the common transport layer 23 by evaporation, an evaporation material of the common transport layer 23 is not deposited or only partially deposited at the position where the partition groove R1 is located because a notch of the partition groove R1 faces the opening area at the side face. Therefore, at the position where the partition groove R1 is located, the common transport layers 23 located at both sides of the partition groove R1 are disconnected.

In order to realize a structure of the partition groove R1, in a first optional implementation, as shown in FIG. 2a, the display substrate further includes: a bottom electrode 24 layer and a partition layer 25 arranged in layer configuration between the base substrate 21 and the pixel defining layer 22, and the bottom electrode 24 layer is located between the base substrate 21 and the partition layer 25.

An orthographic projection of the partition layer 25 on the base substrate 21 is located within an orthographic projection range of the pixel defining layer 22 on the base substrate 21. The partition layer 25 is provided with a first end face a1 facing the opening area, the pixel defining layer 22 located at one side of the partition layer 25 away from the base substrate 21 is provided with a second end face a2 facing the opening area, the first end face a1 retracts in a direction away from the opening area relative to the second end face a2, and the first end face a1 forms a groove bottom of the partition groove R1.

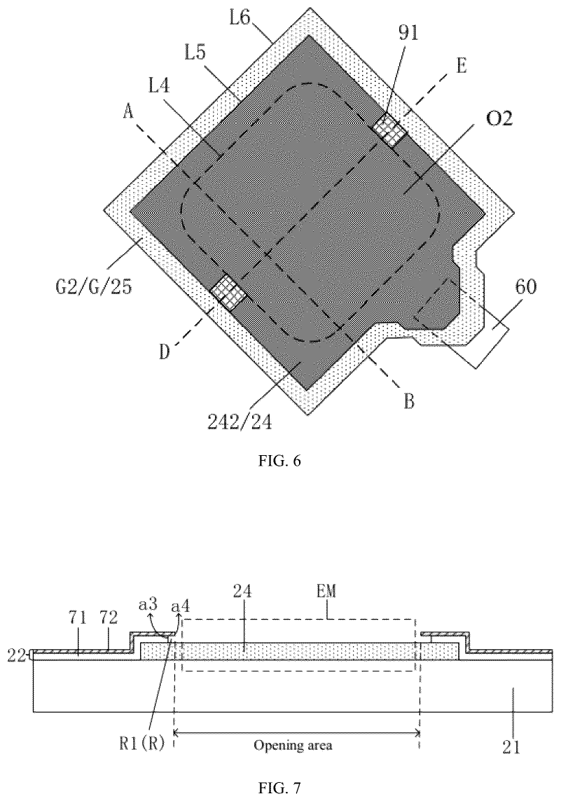

The bottom electrode 24 layer may include a plurality of bottom electrodes 24 separated from each other. Referring to FIG. 5, FIG. 5 schematically shows a schematic diagram of a plane of a structure of one sub-pixel in the display substrate shown in FIG. 4. Referring to FIG. 6, FIG. 6 schematically shows a schematic diagram of a plane of a structure of one sub-pixel in the display substrate shown in FIG. 1. Schematic sectional structural diagrams along dotted lines AB in FIG. 5 and FIG. 6 are as shown in FIG. 2a. As shown in FIG. 2a, FIG. 5 or FIG. 6, the bottom electrode 24 is arranged in one-to-one correspondence with the opening area, and an orthographic projection of the bottom electrode 24 on the base substrate 21 covers an orthographic projection of the opening area of the same sub-pixel on the base substrate 21.

The partition layer 25 may include a plurality of partition parts G separated from each other. As shown in FIG. 2a, the first end face a1 is a surface of one side of the partition portion G facing the opening area. As shown in FIG. 2a, FIG. 5 or FIG. 6, the partition part G may be arranged around the opening area by one circle, and the orthographic projection of the partition part G on the base substrate 21 does not overlap with the orthographic projection of the opening area of the same sub-pixel on the base substrate 21.

As shown in FIG. 5 or FIG. 6, the orthographic projection of the bottom electrode 24 on the base substrate 21 is located within an outer boundary scope of the orthographic projection of the partition part G of the same sub-pixel on the base substrate 21. As shown in FIG. 2a, in the same sub-pixel, the bottom electrode 24 and the partition part G may be contacted with each other.

In a particular implementation, the display substrate may further include: a thin film transistor layer and an insulating layer arranged in layer configuration between the base substrate 21 and the bottom electrode 24 layer, and the thin film transistor layer is located between the base substrate 21 and the insulating layer. The insulating layer may be an organic material such as polyimide, and the like. The insulating layer may play a role in flattening the surface of the display substrate.

Optionally, the display substrate includes a first active area. A plane structural schematic diagram of the first active area is as shown in FIG. 4. Referring to FIG. 5, in the first active area, the plurality of bottom electrodes 24 include a first bottom electrode 241, the plurality of opening areas include a first opening area O1, and the plurality of partition parts G includes a first partition part G1. The first partition part G1 and the first bottom electrode 241 are contacted with each other.

As shown in FIG. 5, an orthographic projection of the first bottom electrode 241 on the base substrate 21 covers an orthographic projection of the first opening area O1 on the base substrate 21. An orthographic projection of the first bottom electrode 241 on the base substrate 21 is located within an outer boundary range of the first partition part G1 on the base substrate 21.

In FIG. 5, an area enclosed by L1 is the first opening area O1. Loop line L2 is a boundary of an orthographic projection of the first bottom electrode 241 on the base substrate 21, and is also an inner boundary of the orthographic projection of the first partition part G1 on the base substrate 21, and loop line L3 is an outer boundary of the orthographic projection of the first partition part G1 on the base substrate 21.

Accordingly, the thin film transistor layer includes: a first thin film transistor and a first switching part 50 connected to a source electrode or a drain electrode of the first thin film transistor.

As shown in FIG. 5, orthographic projections of the first bottom electrode 241 and the first switching part 50 on the base substrate 21 do not intersect or overlap. Orthographic projections of the first partition part G1 and the first switching part 50 on the base substrate 21 intersect or overlap, and the first bottom electrode and the first switching part are connected through a via hole arranged on the insulating layer.

The first active area may be located in a transparent active area, and the bottom electrode 24 layer may be made of a metallic material. Due to the fact that a transmittance of the metallic material is low, by configuring that the orthographic projection of the opaque first bottom electrode 241 on the base substrate 21 and the orthographic projection of the first switching part 50 on the base substrate 21 do not intersect or overlap, a transmittance of the transparent active area can be improved, a photographing effect of an off-screen camera can be improved, and optical diffraction can be reduced.

Moreover, the partition layer 25 may be made of a transparent conducting material. Because the first partition part G1 is connected to the first switching part 50 through the via hole disposed on the insulating layer, and the first partition part G1 is contacted with the first bottom electrode 241, the connection between the first bottom electrode 241 and the first thin film transistor is realized, and signal can be transmitted from the first thin film transistor to the first bottom electrode 241. Moreover, since the material of the first partition part G1 is a transparent conducting material, even if the orthographic projection of the first partition part G1 on the base substrate 21 intersects or overlaps with the orthographic projection of the first switching part 50 on the base substrate 21, the transmittance of the transparent active area may not be affected.

The transparent active area can not only display frames, but also transmit the ambient light. The transparent active area can realize display functions such as virtual reality/augmented reality (VR/AR) and off-screen camera.

Optionally, the display substrate includes a second active area. A schematic diagram of a plane of a structure of the second active area is as shown in FIG. 1. Referring to FIG. 6, in the second active area, the plurality of bottom electrodes 24 include a second bottom electrode 242, and the plurality of opening areas include a second opening area O2. An orthographic projection of the second bottom electrode 242 on the base substrate 21 covers an orthographic projection of the second opening area O2 on the base substrate 21.

Accordingly, the thin film transistor layer includes: a second thin film transistor and a second switching part 60 connected to a source electrode or a drain electrode of the second thin film transistor.

As shown in FIG. 6, orthographic projections of the second bottom electrode 242 and the second switching part 60 on the base substrate 21 intersect or overlap, and the second bottom electrode 242 and the second switching part 60 are connected through a via hole arranged on the insulating layer.

The second active area may be a regular active area, for example, within a non-transparent active area. The bottom electrode 24 layer may be made of a metallic material, and the partition layer 25 may be made of a transparent conducting material. Due to a high conductivity of the metallic material, contact resistance and power consumption can be reduced by arranging the second bottom electrode 242 and the second switching part 60 to be connected through the via hole arranged on the insulating layer.

As shown in FIG. 6, the plurality of partition parts G may include a second partition part G2 located in the second active area. An orthographic projection of the second bottom electrode 242 on the base substrate 21 is located within an outer boundary range of the orthographic projection of the second partition part G2 on the base substrate 21.

In FIG. 6, an area enclosed by L4 is the second opening area O2. Loop line L5 is a boundary of an orthographic projection of the second bottom electrode 242 on the base substrate 21, and is also an inner boundary of the orthographic projection of the second partition part G2 on the base substrate 21, and loop line L6 is an outer boundary of the orthographic projection of the second partition part G2 on the base substrate 21.

In this implementation, a surface material of one side of the bottom electrode 24 layer away from the base substrate 21 may include at least one of the following: a crystalline metallic oxide, an amorphous metallic oxide and a metal.

The surface material of one side of the bottom electrode 24 layer away from the base substrate 21 may further include residual particles of the partition layer 25. The residual particles are at least partially the same as the material of the partition layer 25.

The material of the partition layer 25 may include at least one of the following: an amorphous metallic oxide, a metal, silicon oxide, silicon nitride and silicon oxynitride.

In some embodiments, the surface material of one side of the bottom electrode 24 layer away from the base substrate 21 is crystalline indium tin oxide, and the material of the partition layer 25 is amorphous indium tin oxide. In this way, after the pixel defining layer 22 is formed, the surface material of one side of the bottom electrode 24 layer away from the base substrate 21 may not be etched during the process of wet-etching the amorphous indium tin oxide to form the partition layer 25.

In other embodiments, the surface material of one side of the bottom electrode 24 layer away from the base substrate 21 is crystalline indium tin oxide, and the material of the partition layer 25 is metal silver. In this way, after the pixel defining layer 22 is formed, the surface material of one side of the bottom electrode 24 layer away from the base substrate 21 may not be etched during the process of wet-etching the metal silver to form the partition layer 25.

In some other embodiments, the surface material of one side of the bottom electrode 24 layer away from the base substrate 21 is crystalline or amorphous indium tin oxide, and the material of the partition layer 25 may include silicon nitride and other materials with an etching rate greater than the etching rate of the pixel defining layer 22. After the pixel defining layer 22 is formed, the material such as silicon nitride may be dry-etched to form the partition layer 25.

In this implementation, a main material of the pixel defining layer 22 may be, for example, an organic material such as polyimide, which is not limited by the present disclosure.

For example, a thickness of the bottom electrode 24 may be greater than or equal to 60 angstroms, and less than or equal to 300 angstroms in a normal direction of the base substrate.

For example, a thickness of the partition layer 25 may be greater than or equal to 60 angstroms, and less than or equal to 300 angstroms in the normal direction of the base substrate.

In this implementation, a dimension of the partition groove R1 in the normal direction of the base substrate 21 can be adjusted by adjusting the thickness of the partition layer 25 in the normal direction of the base substrate 21.

Optionally, as shown in FIG. 2b, the display substrate may further include: a composite electrode layer arranged between the base substrate 21 and the pixel defining layer 22.

The composite electrode layer includes a plurality of composite electrodes 27, and the composite electrode 27 includes a middle pattern 271 and an edge pattern 272 surrounding the middle pattern 271. Orthographic projections of the middle pattern 271 and the pixel defining layer 22 on the base substrate 21 do not intersect or overlap, and orthographic projections of at least part of the edge pattern 272 and the pixel defining layer 22 on the base substrate 21 intersect or overlap.

The middle pattern 271 and the edge pattern 272 at least include a material with the same element but different structures, and the middle pattern 271 and the edge pattern 272 are at least partially located on the same surface of the same layer.

For example, the middle pattern 271 and the edge pattern 272 may both include indium tin oxide. The middle pattern 271 includes crystalline indium tin oxide, and the edge pattern 272 includes amorphous indium tin oxide.

In a particular implementation, at least parts of the middle pattern 271 and the edge pattern 272 can be arranged in the same layer, so that at least parts of the middle pattern 271 and the edge pattern 272 can be located on the same surface in the same layer. For example, a composite electrode 27 layer may include a bottom electrode 24 layer and a partition layer 25 arranged in layer configuration between the base substrate 21 and the pixel defining layer 22. Accordingly, the middle pattern 271 includes a middle area of the bottom electrode 24, and the edge pattern 272 includes an edge area of the bottom electrode 24 and a partition part G surrounding or covering the edge area. In this example, a bottom electrode part in the middle pattern 271 and bottom electrode part in the edge pattern 272 are arranged in the same layer.

In order to realize a structure of the partition groove R1, in a second optional implementation, as shown in FIG. 7 or FIG. 8, the pixel defining layer 22 includes: a first material layer 71 and a second material layer 72 which are arranged in layer configuration, and the first material layer 71 is located between the base substrate 21 and the second material layer 72.

The first material layer 71 is provided with a third end face a3 facing the opening area, the second material layer 72 is provided with a fourth end face a4 facing the opening area, the third end face a3 retracts in a direction away from the opening area relative to the fourth end face a4, and the third end face a3 forms a groove bottom of the partition groove R1.

It should be noted that the third end face a3 and the fourth end face a4 are the end faces of the first material layer 71 and the second material layer 72 facing the same opening area. The first end face a1 retracts relative to the second end face a2 in a direction away from the same opening area.

As shown in FIG. 7, the bottom electrode 24 layer may be further arranged between the base substrate 21 and the pixel defining layer 22, and the bottom electrode 24 layer includes a plurality of bottom electrodes 24. Orthographic projections of the bottom electrodes 24 on the base substrate 21 cover an orthographic projection of the opening area of the same sub-pixel on the base substrate 21. In this case, a the surface of the second material layer 72 opposite to the bottom electrode 24 constitutes a groove wall of the partition groove R1, and the third end surface a3 constitutes a groove bottom of the partition groove R1.

In a particular implementation, the third end face a3 and the fourth end face a4 may be respectively formed by two-time dry-etching processes, or may be formed by one-time dry-etching process at the same time.

When the third end face a3 and the fourth end face a4 are simultaneously formed by one-time dry-etching process, an etching rate of the first material layer 71 is higher than an etching rate of the second material layer 72 by adjusting a component of etching gas or etching solution, or adjusting materials of the first material layer 71 and the second material layer 72, so that the third end face a3 can retract relative to the fourth end face a4 in a direction away from the opening area.

Main materials of the first material layer 71 and the second material layer 72 may both be inorganic material. The inorganic material may include at least one of the following: silicon oxide, silicon nitride, silicon oxynitride, metal, and the like. The metal may include titanium, aluminum, and the like.

In order to make the etching rate of the second material layer 72 be less than the etching rate of the first material layer 71, for example, the main material of the first material layer 71 is silicon nitride, and the main material of the second material layer 72 is silicon oxide; or the main material of the first material layer 71 is silicon oxynitride, and the main material of the second material layer 72 is silicon oxide; or the main material of the first material layer 71 is aluminum, and the main material of the second material layer 72 is titanium; or the like.

Optionally, a thickness of the first material layer 71 may be greater than or equal to 100 angstroms, and less than or equal to 1,000 angstroms.

Optionally, a thickness of the second material layer 72 may be greater than or equal to 100 angstroms, and less than or equal to 1,000 angstroms.

Optionally, as shown in FIG. 8, the pixel defining layer 22 further includes: a third material layer 81 arranged between the first material layer 71 and the base substrate 21. The third material layer 81 is provided with a fifth end face a5 facing the opening area. The third end face a3 also retracts in a direction away from the opening area relative to the fifth end face a5.

It should be noted that the first end face a1 and the third end face a3 are the end faces of the first material layer 71 and the third material layer 81 facing the same opening area. The first end face a1 retracts relative to the third end face a3 in a direction away from the same opening area.

As shown in FIG. 8, the surface of the second material layer 72 opposite to the third material layer 81 constitutes a groove wall of the partition groove R1, and the third end surface a3 constitutes a groove bottom of the partition groove R1.

In a particular implementation, the third end face a3, the fourth end face a4 and the fifth end face a5 may be respectively formed by three-time dry-etching processes, or may be formed by one-time dry-etching process at the same time.

When the third end face a3, the fourth end face a4 and the fifth end face a5 are simultaneously formed by one-time dry-etching process, the etching rate of the first material layer 71 is higher than the etching rate of the second material layer 72 and the third material layer 81 by adjusting the component of the etching gas or etching solution, or adjusting the materials of the first material layer 71, the second material layer 72 and the third material layer 81, so that the third end face a3 can retract relative to the fourth end face a4 and the fifth end face a5 in the direction away from the opening area.

Main materials of the first material layer 71, the second material layer 72 and the third material layer 81 may all be an inorganic material. The inorganic material may include at least one of the following: silicon oxide, silicon nitride, silicon oxynitride, metal, and the like. The metal may include titanium, aluminum and the like.

In order to make the etching rate of the first material layer 71 be greater than the etching rate of the second material layer 72 and the etching rate of the third material layer, for example, the material of the first material layer 71 is silicon nitride, the material of the second material layer 72 is silicon oxynitride, and the material of the third material layer 81 is silicon oxide; or the material of the first material layer 71 is silicon nitride, the material of the second material layer 72 is silicon oxide, and the material of the third material layer 81 is silicon oxide; or the material of the first material layer 71 is silicon oxynitride, the material of the second material layer 72 is silicon oxide, and the material of the third material layer 81 is silicon oxide; or the material of the first material layer 71 is aluminum, the material of the second material layer 72 is titanium, and the material of the third material layer 81 is titanium and the like.

In this implementation, by adjusting the thickness of the first material layer 71, the dimension of the partition groove R1 in the normal direction of the base substrate 21 can be adjusted. By adjusting the etching time and other parameters, a retraction amount of the third end surface a3 relative to the fourth end surface a4 or the fifth end surface a5, i.e., a groove depth of the partition groove R1 in the plane at which the base substrate 21 is located, can be adjusted.

In a first implementation, by configuring that the partition groove R1 is formed by setting the partition layer 25, when the main material of the partition layer 25 is metal or metallic oxide, compared with a solution of using silicon oxide, silicon nitride, silicon oxynitride and other materials to form the partition groove in a second implementation, an adhesion between membrane layers is higher, so that peeling or falling off can be avoided in a folding process, and a stability and a service life of a foldable product can be improved.

Optionally, in the plane at which the base substrate 21 is located, the groove depth of the partition groove R1 is greater than or equal to 0.1 micron and less than or equal to 10 microns. The groove depth of the partition groove R1 refers to a minimum distance between the groove bottom facing the opening area and the opening area.

Optionally, a dimension of the partition groove R1 is greater than or equal to 100 angstroms, and less than or equal to 10,000 angstroms in the normal direction of the base substrate 21. Further, the dimension may be greater than or equal to 200 angstroms, and less than or equal to 1,500 angstroms, or the dimension may be greater than or equal to 300 angstroms, and less than or equal to 1,000 angstroms. The dimension may be adjusted according to the actual needs in a particular implementation.

When the dimension of the partition groove R1 in the normal direction of the base substrate 21 is located within the above range, the common transport layer 23 may be partitioned at the position of the partition groove R1. Meanwhile, as the organic material is filled in the partition groove R1 before the top electrode layer 26 is formed, an evaporated material of the top electrode layer 26 is not easily disconnected at the partition groove R1, so that the top electrode layer 26 can be lapped at the partition groove R1 can be implemented.

In actual implementation, by adjusting the dimension of the partition groove R1 in the normal direction of the base substrate 21, it can be implemented that the top electrode layer 26 can be partitioned or not at the position of the partition groove R1.

In a particular implementation, as shown in FIG. 2a, the display substrate may also include: the top electrode layer 26 arranged at one side of the common transport layer 23 away from the base substrate 21. In order to ensure the normal power-on and light emission of a light emitting device EM of each sub-pixel, optionally, the top electrode layer in the at least two adjacent opening areas and the top electrode layer on the pixel defining layer 22 between the at least adjacent two opening areas are at least partially lapped.

As shown in FIG. 2a, the top electrode layer 26 located at one side of the partition structure R close to a light emitting area is at least partially lapped with the top electrode layer 26 located at one side of the partition structure R away from the light emitting area.

Since the common transport layer 23 is made before the top electrode layer 26, and the common transport layer 23 has the function of smoothing the partition structure R, the top electrode layer 26 may also be lapped at the position where the partition structure R is located.

Optionally, the partition groove R1 is a closed structure surrounding the opening area by one circle, so that lateral transport of carriers in the common transport layer 23 can be completely reduced in a direction surrounding the opening area by one circle, and a signal crosstalk problem between different sub-pixels can be completely improved.

Optionally, the partition groove R1 is a non-closed structure surrounding the opening area by one circle. In this way, the common transport layer 23 may not be partitioned at the position where the partition groove R1 is not disposed around the opening area, so that a conductive channel may be reserved for the subsequent lapping of the top electrode layer 26, preventing the top electrode layer 26 from being completely disconnected at the position where the partition groove R1 is located, and ensuring the mutual lapping of the top electrode layers 26 located at both sides of the partition groove R1.

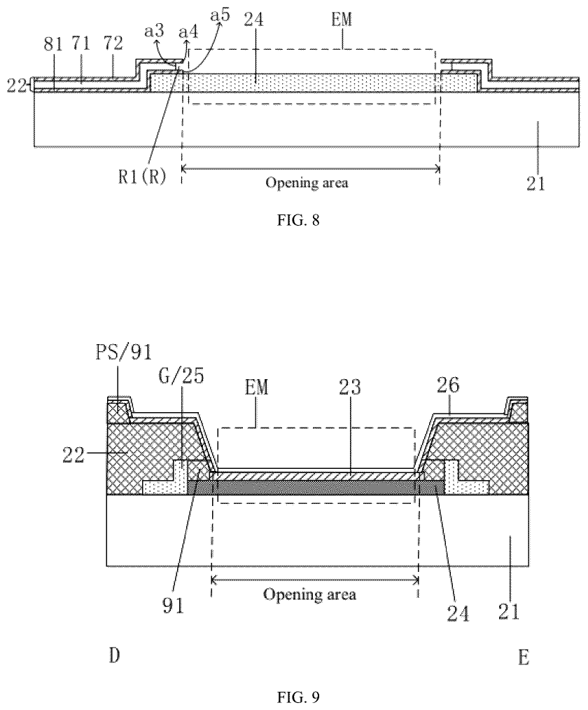

Optionally, referring to FIG. 9, FIG. 9 schematically shows a schematic sectional structural diagram of a sub-pixel shown in FIG. 5 and FIG. 6 along a dotted line DE. As shown in FIG. 9, the display substrate further includes: a filling layer 91 arranged between the pixel defining layer 22 and the common transport layer 23. Referring to FIG. 5 or FIG. 6, orthographic projections of the filling layer 91 and the partition groove R1 on the base substrate 21 intersect or overlap respectively, and the filling layer 91 is configured for filling the partition groove R1 at the corresponding position.

In FIG. 5 or FIG. 6, the orthographic projection of the partition groove R1 on the base substrate 21 is located between a loop line L1 and a loop line L2. The orthographic projection of the filling layer 91 on the base substrate 21 covers a part of the orthographic projection of the partition groove R1 on the base substrate 21.

As the filling layer 91 can fill the partition groove R1 at the corresponding position, the top electrode layer 26 formed subsequently can be lapped at least at the position where the filling layer 91 is located. An lapping channel of the top electrode layer 26 is formed by arranging the filling layer 91, and the arrangement of the filling layer 91 makes the partition groove R1 be a non-closed structure surrounding the opening area, thereby allowing the top electrode layer 26 to be partitioned at the corresponding position of the partition groove R1 due to process fluctuation, and increasing a process window.

Optionally, as shown in FIG. 9, the filling layer 91 may further include: a spacer column PS arranged at one side of the pixel defining layer 22 away from the base substrate 21, and the spacer column PS may be used to support an evaporation mask.

A dimension of the spacer column PS may be designed as needed. For example, a thickness of the spacer column PS may be 1.5 microns. In a plane direction where the base substrate 21 is located, the dimension of the spacer column PS may be 10 microns.

Optionally, the filling layer 91 and the pixel defining layer 22 may be formed synchronously by using a halftone mask, thereby saving a patterning process.

Optionally, the filling layer 91 and the pixel defining layer 22 may be formed respectively by using different common masks. In this way, higher accuracy can be achieved, exposure energy can be reduced, cost can be reduced and productivity can be improved.

The opening area is configured for arranging a light emitting device EM. The light emitting device EM may be an organic light-emitting diode (OLED), a mini light-emitting diode (Mini LED), a micro light-emitting diode (Micro LED), a quantum dot light-emitting diode (QLED), and the like, which is not limited by the present disclosure.

Optionally, the common transport layer 23 includes at least one of the following membrane layers: a hole injection layer, a hole transport layer, a charge generating layer, a light emitting layer, an electron transport layer, electron injection layer and other membrane layers which are arranged in layer configuration.

For example, the membrane layers such as the hole injection layer, the hole transport layer, the charge generating layer, the electron transport layer and the electron injection layer may be formed by evaporation with an Open Mask.

For example, the light emitting layer may be formed by evaporation with a fine metal mask (FMM). In the actual evaporation process, due to evaporation deviation, light emitting layers of different sub-pixels may be lapped with each other.

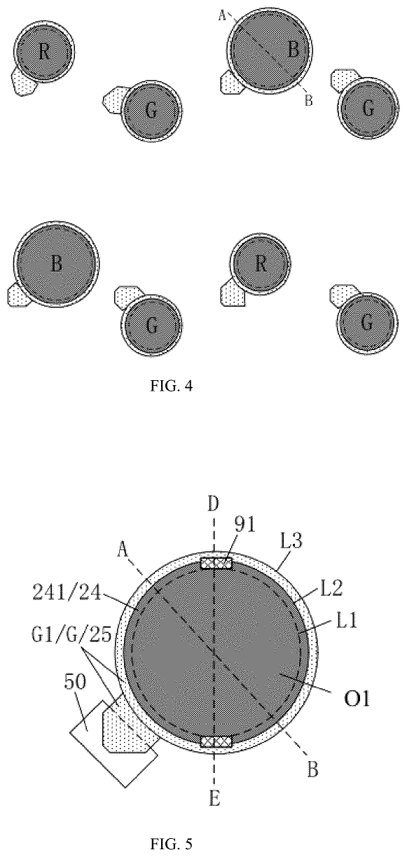

In a particular implementation, the light emitting device EM may include one light emitting layer, and may also include a plurality of light emitting layers arranged in layer configuration in the normal direction of the base substrate 21. Referring to FIG. 3, FIG. 3 schematically shows a schematic sectional structural diagram of a light emitting device. As shown in FIG. 3, a plurality of light emitting layers include a first light emitting layer 31 and a second light emitting layer 32 which are arranged in layer configuration. The plurality of light emitting layers may be connected in series with each other through a charge generating layer 33 to form a series light emitting device EM. In FIG. 3, the charge generating layer 33 is located between the first light emitting layer 31 and the second light emitting layer 32.

In this case, the common transport layer 23 includes the charge generating layer 33. Since the charge generating layer 33 is more conductive, a problem of signal crosstalk between different sub-pixels can be improved more significantly by setting the partition structure R on the charge generating layer 33 to partition the charge generating layer 33.

In the series light emitting device EM, the charge generating layer 33 may inject carriers (such as holes or electrons) into an adjacent light emitting layer. For example, as shown in FIG. 3, for the first light emitting layer 31, a part of carriers are provided by the bottom electrode 24 and the top electrode layer 26, and another part of carriers are generated in the charge generating layer 33. Therefore, the series light emitting device EM has the advantages of long service life and low power consumption.

It should be noted that the thickness herein refers to a dimension in a direction perpendicular to a plane where a corresponding membrane layer is located. In addition, in the actual process, due to the limitation of process conditions or other factors, similarities of the above features are not exactly the same, and there may be some deviations, so the same relationship between the above features belongs to the protection scope of the present disclosure as long as the above conditions are substantially met. For example, the above-mentioned sameness may be sameness allowed within an allowable range of error.

The present disclosure provides a display device, including any one of the provided display substrates.

As the display device includes the above display substrate, those skilled in the art can understand that the display device has the advantages of the display substrate provided by the present disclosure, which will not be described in detail here.

It should be noted that the display device in the present embodiment may be any product or component with 2D or 3D display function, such as a display panel, electronic paper, a mobile phone, a tablet computer, a TV set, a notebook computer, a digital photo frame, a virtual reality device, an augmented reality device, an off-screen camera device, a navigator, and the like.

The present disclosure provides a manufacturing method of a display substrate. Referring to FIG. 2a, the manufacturing method includes the following steps.

Step S01, a base substrate 21 is provided.

Step S02, a pixel defining layer 22 is formed at one side of the base substrate 11, the pixel defining layer 22 is configured for defining a plurality of opening areas. The opening area is configured for setting a light emitting device EM of a sub-pixel.

Step S03, a common transport layer 23 is formed at one side of the pixel defining layer 22 away from the base substrate 21.

A surface of one side away from the base substrate of the pixel defining layer between at least two adjacent opening areas is covered by the common transport layer, and at least part of a side face of the pixel defining layer facing at least one opening area is not covered by the common transport layer; and,
orthographic projections of the common transport layers in the at least two adjacent opening areas on the base substrate and orthographic projections of the common transport layers on the pixel defining layers between the at least two adjacent opening areas on the base substrate are continuous.

Any of the display substrates provided can be prepared by the manufacturing method provided by the present disclosure.

In an optional implementation, the pixel defining layer includes a partition structure R, the partition structure R includes a partition groove R1 arranged in a side face of the pixel defining layer 22 facing the opening area, and the step S02 may specifically be as follows.

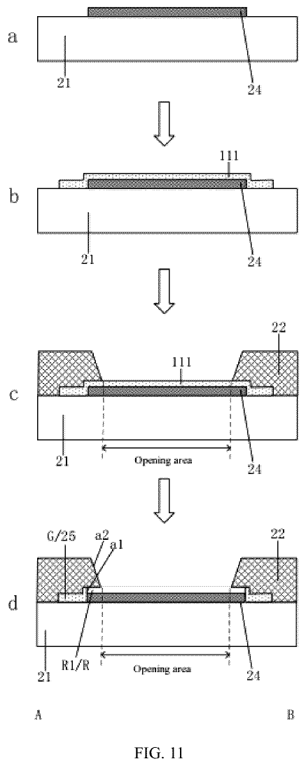

Step S11, a bottom electrode 24 layer is formed at one side of the base substrate 21, the bottom electrode layer 24 including a plurality of bottom electrodes 24, and orthographic projections of the plurality of bottom electrodes 24 on the base substrate 21 cover orthographic projections of the plurality of opening areas on the base substrate 21. Referring to FIG. a in FIG. 11, which schematically shows a schematic sectional structural diagram of the display substrate with the bottom electrode layer completely prepared.

Step S12, a partition material layer 111 is formed at one side of the bottom electrode 24 layer away from the base substrate 21 by patterning, an orthographic projection of the partition material layer 111 on the base substrate 21 covers the orthographic projections of the plurality of bottom electrodes 24 on the base substrate 21. Referring to FIG. b in FIG. 11, which schematically shows a schematic sectional structural diagram of the display substrate with the partition material layer completely prepared.

Step S13, a pixel defining layer 22 is formed at one side of the partition material layer away from the base substrate 21. Referring to FIG. c in FIG. 11, which schematically shows a schematic sectional structural diagram of the display substrate with the pixel defining layer completely prepared.

Step S14, the partition material layer located in the opening area is etched to form a partition layer 25.

Referring to FIG. d in FIG. 11, which schematically shows a schematic sectional structural diagram of the display substrate with the partition layer completely prepared. As shown in FIG. d in FIG. 11, an orthographic projection of the partition layer 25 on the base substrate 21 is located within an orthographic projection range of the pixel defining layer 22 on the base substrate 21. The partition layer 25 is provided with a first end face a1 facing the opening area, the pixel defining layer 22 located at one side of the partition layer 25 away from the base substrate 21 is provided with a second end face a2 facing the opening area, the first end face a1 retracts in a direction away from the opening area relative to the second end face a2, and the first end face a1 forms a groove bottom of the partition groove R1.

In a particular implementation, by adjusting parameters such as etching time in the step S14, a groove depth of the partition groove R1 in a plane at which the base substrate 21 is located may be adjusted.

In order to ensure that a surface of one side of the bottom electrode 24 layer away from the base substrate 21 is not etched in the process of etching the partition material layer in the opening area in the step S14, a surface material of one side of the bottom electrode 24 layer away from the base substrate 21 may be crystallized before the step S14, and it is ensured that a material of the partition layer 25 may not be crystallized.

For example, when the surface material of one side of the bottom electrode 24 layer away from the base substrate 21 and the material of the partition layer 25 are both metallic oxides such as indium tin oxide, after the step S1i and before the step S12, the above manufacturing method may further include the following step.

Step S21, the surface material of one side of the bottom electrode 24 layer away from the base substrate 21 is crystallized. Accordingly, after the step S13 and before the step S14, the method may include the following step.

Step S22, the pixel defining layer 22 is subjected to thermal baking treatment at a first preset temperature. The first preset temperature is lower than a crystallization temperature of the partition material layer.

For example, when the surface material of one side of the bottom electrode 24 layer away from the base substrate 21 is a metallic oxide such as indium tin oxide and the material of the partition layer 25 is a metal, after the step S13 and before the step S14, the above manufacturing method may further include the following step.

Step S31, the pixel defining layer 22 is subjected to thermal baking treatment at a second preset temperature. The second preset temperature is greater than or equal to a crystallization temperature of the above surface material.

The following provides a process for manufacturing a display substrate which includes a first active area (located in a transparent active area) and a second active area, and may specifically include the following steps.

Step 1, a base substrate 21 is provided, and a thin film transistor layer and an insulating layer are sequentially formed at one side of the base substrate 21. The thin film transistor layer includes: a first thin film transistor, a second thin film transistor, a first switching part 50 connected to a source electrode or a drain electrode of the first thin film transistor, and a second switching part 60 connected to a source electrode or a drain electrode of the second thin film transistor.

Step 2, a bottom electrode 24 layer is formed at one side of the insulating layer away from the base substrate 21. Materials of the bottom electrode 24 layer are an indium tin oxide layer, a silver layer and an indium tin oxide layer which are arranged in layer configuration.

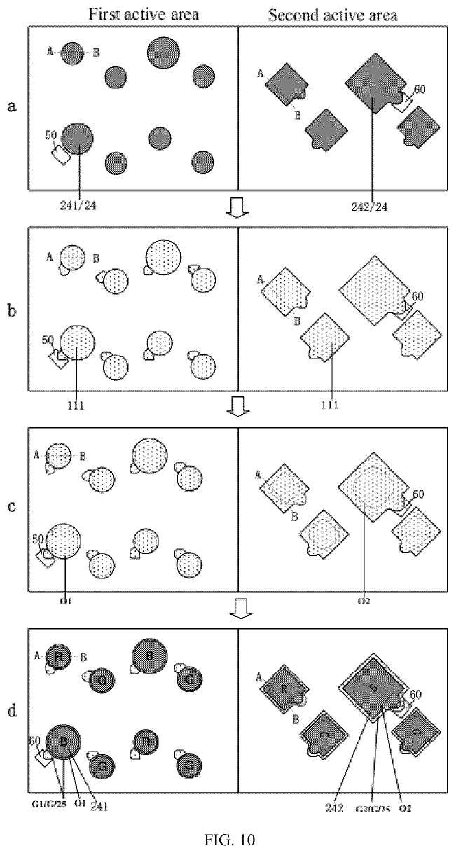

Referring to FIG. a in FIG. 10, which schematically shows a schematic diagram of a plane of a structure of the display substrate with the bottom electrode layer completely prepared. A schematic sectional structural diagram along a dotted line AB in FIG. a in FIG. 10 is as shown in FIG. a in FIG. 11.

As shown in FIG. a in FIG. 10, the bottom electrode 24 layer includes a plurality of bottom electrodes 24. The plurality of bottom electrodes 24 include: a first bottom electrode 241 located in a first active area and a second bottom electrode 242 located in a second active area. Orthographic projections of the first bottom electrode 241 and the first switching part 50 on the base substrate 21 do not intersect or overlap, so that a transmittance of a transparent active area can be improved. Orthographic projections of the second bottom electrode 242 and the second switching part 60 on the base substrate 21 intersect or overlap, and the second bottom electrode 242 and the second switching part 60 are connected through a via hole arranged on the insulating layer.

Step 3, the bottom electrode 24 layer is subjected to a thermal baking treatment, wherein a thermal baking temperature may be adjusted between 100° C. and 400° C., so that the indium tin oxide in the bottom electrode 24 layer is crystallized.

Step 4, a partition material layer 111 is formed at one side of the bottom electrode 24 away from the base substrate 21 by patterning, and a material of the partition material layer 111 is indium tin oxide.

Referring to FIG. b in FIG. 10, which schematically shows a schematic diagram of a plane of a structure of the display substrate with the partition material layer completely prepared. A schematic sectional structural diagram along a dotted line AB in FIG. b in FIG. 10 is as shown in FIG. b in FIG. 11.

As shown in FIG. b in FIG. 11, an orthographic projection of the partition material layer 111 on the base substrate 21 covers orthographic projections of a plurality of bottom electrodes 24 on the base substrate 21. As shown in FIG. b in FIG. 10, the orthographic projection of the partition material layer 111 on the base substrate 21 and orthographic projections of the first switching part 50 and the second switching part 60 on the base substrate 21 intersect or overlap. The patterning above may include processes such as wet-etching.

Step 5, a pixel defining layer 22 is formed at one side of the partition material layer 111 away from the base substrate 21. A material of the pixel defining layer 22 is polyimide.

Referring to FIG. c in FIG. 10, which schematically shows a schematic diagram of a plane of a structure of the display substrate with the pixel defining layer completely prepared. A schematic sectional structural diagram along a dotted line AB in FIG. c in FIG. 10 is as shown in FIG. c in FIG. 11.

As shown in FIG. c in FIG. 10, the pixel defining layer 22 is configured for defining and forming a plurality of opening areas. The plurality of opening areas include: a first opening area O1 located in the first active area and a second opening area O2 located in the second active area. As shown in FIG. c in FIG. 11, an orthographic projection of the first bottom electrode 241 on the base substrate 21 covers an orthographic projection of the first opening area O1 on the base substrate 21, and an orthographic projection of the second bottom electrode 242 on the base substrate 21 covers an orthographic projection of the second opening area O2 on the base substrate 21.

Step 6, the pixel defining layer 22 is subjected to thermal baking treatment at a first preset temperature. The first preset temperature is lower than a crystallization temperature of indium tin oxide to avoid crystallization of the partition material layer. For example, the first preset temperature may be adjusted between 50° C. and 300° C.

Step 7, the partition material layer located in the opening area is wet-etched to form a partition layer 25. Because the indium tin oxide in the bottom electrode 24 layer is already crystallized, but the indium tin oxide in the partition material layer is not crystallized, the amorphous indium tin oxide in the partition material layer is etched in this step, but the crystallized indium tin oxide in the bottom electrode 24 may not be etched.

Referring to FIG. d in FIG. 10, which schematically shows a schematic diagram of a plane of a structure of the display substrate with the partition layer completely prepared. A schematic sectional structural diagram along a dotted line AB in FIG. d in FIG. 10 is as shown in FIG. d in FIG. 11.

As shown in FIG. d in FIG. 11, an orthographic projection of the partition layer 25 on the base substrate 21 is located within an orthographic projection range of the pixel defining layer 22 on the base substrate 21. The partition layer 25 is provided with a first end face a1 facing the opening area, the pixel defining layer 22 located at one side of the partition layer 25 away from the base substrate 21 is provided with a second end face a2 facing the opening area, the first end face a1 retracts in a direction away from the opening area relative to the second end face a2, and the first end face a1 forms a groove bottom of the partition groove R1.

As shown in FIG. d in FIG. 10, the partition layer 25 includes a first partition part G1 located in the first active area and a second partition part G2 located in the second active area. The first partition part G1 and the first bottom electrode 241 are contacted with each other, and the first partition part G1 is arranged around a periphery of the first bottom electrode 241. Orthographic projections of the first partition part G1 and the first switching part 50 on the base substrate 21 intersect or overlap and the first partition part G1 and the first switching part 50 are connected through a via hole arranged on the insulating layer. The second partition part G2 and the second bottom electrode 242 are contacted with each other, and arranged around a periphery of the second bottom electrode 242.

After that, a filling layer, a first light emitting layer, a charge generating layer, a second light emitting layer and a top electrode layer may be sequentially formed at one side of the pixel defining layer 22 away from the base substrate 21.

The embodiments of the description are described in the mode of progression, each of the embodiments emphatically describes the differences from the other embodiments, and the same or similar parts of the embodiments may refer to each other.

Finally, it should also be noted that, in the present text, relation terms such as first and second are merely intended to distinguish one entity or operation from another entity or operation, and that does not necessarily require or imply that those entities or operations have therebetween any such actual relation or order. Furthermore, the terms “include”, “include” or any variants thereof are intended to cover non-exclusive inclusions, so that processes, methods, articles or devices that include a series of elements do not only include those elements, but also include other elements that are not explicitly listed, or include the elements that are inherent to such processes, methods, articles or devices. Unless further limitation is set forth, an element defined by the wording “including a . . . ” does not exclude additional same element in the process, method, article or device including the element.

The task dispatching method and apparatus, the computing and processing device, the computer program and the computer-readable medium according to the present disclosure have been described in detail above. The principle and the embodiments of the present disclosure are described herein with reference to the particular examples, and the description of the above embodiments is merely intended to facilitate to understand the method according to the present disclosure and its core concept. Moreover, for a person skilled in the art, according to the concept of the present disclosure, the particular embodiments and the range of application may be varied. In conclusion, the contents of the description should not be understood as limiting the present disclosure.

A person skilled in the art, after considering the description and implementing the invention disclosed herein, will readily envisage other embodiments of the present disclosure. The present disclosure aims at encompassing any variations, uses or adaptive alternations of the present disclosure, wherein those variations, uses or adaptive alternations follow the general principle of the present disclosure and include common knowledge or common technical means in the art that are not disclosed by the present disclosure. The description and the embodiments are merely deemed as exemplary, and the true scope and spirit of the present disclosure are presented by the following claims.

It should be understood that the present disclosure is not limited to the accurate structure that has been described above and shown in the drawings, and may have various modifications and variations without departing from its scope. The scope of the present disclosure is merely limited by the appended claims.

The “one embodiment”, “an embodiment” or “one or more embodiments” as used herein means that particular features, structures or characteristics described with reference to an embodiment are included in at least one embodiment of the present disclosure. Moreover, it should be noted that here an example using the wording “in an embodiment” does not necessarily refer to the same one embodiment.

The description provided herein describes many concrete details. However, it may be understood that the embodiments of the present disclosure may be implemented without those concrete details. In some of the embodiments, well-known processes, structures and techniques are not described in detail, so as not to affect the understanding of the description.

In the claims, any reference signs between parentheses should not be construed as limiting the claims. The word “include” does not exclude elements or steps that are not listed in the claims. The word “a” or “an” preceding an element does not exclude the existing of a plurality of such elements. The present disclosure may be implemented by means of hardware including several different elements and by means of a properly programmed computer. In unit claims that list several devices, some of those devices may be embodied by the same item of hardware. The words first, second, third and so on do not denote any order. Those words may be interpreted as names.

Finally, it should be noted that the above embodiments are merely intended to explain the technical solutions of the present disclosure, and not to limit them. Although the present disclosure is explained in detail with reference to the above embodiments, a person skilled in the art should understand that he may still modify the technical solutions set forth by the above embodiments, or make equivalent substitutions to part of the technical features of them. However, those modifications or substitutions do not make the essence of the corresponding technical solutions depart from the spirit and scope of the technical solutions of the embodiments of the present disclosure.

1. A display substrate, comprising:
a base substrate;
a pixel defining layer arranged at one side of the base substrate, the pixel defining layer being configured for defining a plurality of opening areas, and the opening area being configured for arranging a light emitting device; and
a common transport layer arranged at one side of the pixel defining layer away from the base substrate;
wherein a surface of one side away from the base substrate of the pixel defining layer between at least two adjacent opening areas is covered by the common transport layer, and at least part of a side face of the pixel defining layer facing at least one opening area is not covered by the common transport layer; and
orthographic projections of the common transport layers in the at least two adjacent opening areas on the base substrate and orthographic projections of the common transport layers on the pixel defining layers between the at least two adjacent opening areas on the base substrate are continuous.

2. The display substrate according to claim 1, wherein the pixel defining layer comprises a partition structure, and the partition structure comprises:
a partition groove arranged in a side face of the pixel defining layer facing the at least one opening area, and a notch of the partition groove facing the at least one opening area.

3. The display substrate according to claim 2, wherein the display substrate further comprises:
a bottom electrode layer and a partition layer arranged in layer configuration between the base substrate and the pixel defining layer, wherein the bottom electrode layer is located between the base substrate and the partition layer;
wherein an orthographic projection of the partition layer on the base substrate is located within an orthographic projection range of the pixel defining layer on the base substrate; and the partition layer is provided with a first end face facing the opening area, the pixel defining layer located at one side of the partition layer away from the base substrate is provided with a second end face facing the opening area, the first end face retracts in a direction away from the opening area relative to the second end face, and the first end face forms a groove bottom of the partition groove.

4. The display substrate according to claim 3, wherein the display substrate comprises a first active area; in the first active area, the bottom electrode layer comprises a first bottom electrode, the plurality of opening areas comprise a first opening area, and the partition layer comprises a first partition part; and an orthographic projection of the first bottom electrode on the base substrate covers an orthographic projection of the first opening area on the base substrate, and the first partition part and the first bottom electrode are contacted with each other; and
the display substrate further comprises: a thin film transistor layer and an insulating layer arranged in layer configuration between the base substrate and the bottom electrode layer, wherein the thin film transistor layer is located between the base substrate and the insulating layer; and the thin film transistor layer comprises: a first thin film transistor and a first switching part connected to a source electrode or a drain electrode of the first thin film transistor;
wherein orthographic projections of the first bottom electrode and the first switching part on the base substrate do not intersect or overlap; and orthographic projections of the first partition part and the first switching part on the base substrate intersect or overlap, and the first bottom electrode and the first switching part are connected through a via hole arranged on the insulating layer.

5. The display substrate according to claim 4, wherein the first active area is located within a transparent active area, the bottom electrode layer comprises a metallic material, and the partition layer comprises a transparent conducting material.

6. The display substrate according to claim 3, wherein the display substrate comprises a second active area; in the second active area, the bottom electrode layer comprises a second bottom electrode, and the plurality of opening areas comprise a second opening area; and an orthographic projection of the second bottom electrode on the base substrate covers an orthographic projection of the second opening area on the base substrate; and
the display substrate further comprises: a thin film transistor layer and an insulating layer arranged in layer configuration between the base substrate and the bottom electrode layer, wherein the thin film transistor layer is located between the base substrate and the insulating layer; and the thin film transistor layer comprises: a second thin film transistor and a second switching part connected to a source electrode or a drain electrode of the second thin film transistor;
wherein orthographic projections of the second bottom electrode and the second switching part on the base substrate intersect or overlap, and the second bottom electrode and the second switching part are connected through a via hole arranged on the insulating layer.

7. The display substrate according to claim 3, wherein a surface material of one side of the bottom electrode layer away from the base substrate comprises at least one of the following: a crystalline metallic oxide, an amorphous metallic oxide, a metal and residual particles of the partition layer; and/or
a material of the partition layer comprises at least one of the following: an amorphous metallic oxide, a metal, silicon oxide, silicon nitride and silicon oxynitride; and/or
a main material of the pixel defining layer is an organic material.

8. The display substrate according to claim 1, wherein the display substrate further comprises: a composite electrode layer arranged between the base substrate and the pixel defining layer;
wherein the composite electrode layer comprises a plurality of composite electrodes, the composite electrode comprises a middle pattern and an edge pattern surrounding the middle pattern, orthographic projections of the middle pattern and the pixel defining layer on the base substrate do not intersect or overlap, and orthographic projections of at least part of the edge pattern and the pixel defining layer on the base substrate intersect or overlap; and
the middle pattern and the edge pattern at least comprise a material with the same element but different structures, and the middle pattern and the edge pattern are at least partially located on a same surface of a same layer.

9. The display substrate according to claim 2, wherein the pixel defining layer comprises:
a first material layer and a second material layer which are arranged in layer configuration, wherein the first material layer is located between the base substrate and the second material layer;
wherein the first material layer is provided with a third end face facing the opening area, the second material layer is provided with a fourth end face facing the opening area, the third end face retracts in a direction away from the opening area relative to the fourth end face, and the third end face forms a groove bottom of the partition groove.

10. The display substrate according to claim 9, wherein the pixel defining layer further comprises:
a third material layer arranged between the first material layer and the base substrate, and the third material layer being provided with a fifth end face facing the opening area; wherein the third end face further retracts in a direction away from the opening area relative to the fifth end face.

11. The display substrate according to claim 9, wherein a main material of the pixel defining layer is an inorganic material.

12. The display substrate according to claim 11, wherein the inorganic material comprises at least one of the following: silicon oxide, silicon nitride, silicon oxynitride and metal.

13. The display substrate according to claim 2, wherein the display substrate further comprises:
a filling layer arranged between the pixel defining layer and the common transport layer, wherein an orthographic projection of the filling layer on the base substrate and an orthographic projection of the partition groove on the base substrate intersect or overlap, and the filling layer is configured for filling the partition groove at a corresponding position.

14. The display substrate according to claim 2, wherein a groove depth of the partition groove is greater than or equal to 0.1 micron, and less than or equal to 10 microns in a plane at which the base substrate is located.

15. The display substrate according to claim 2, wherein a dimension of the partition groove is greater than or equal to 100 angstroms, and less than or equal to 10,000 angstroms in a normal direction of the base substrate.

16. The display substrate according to claim 2, wherein the partition groove is a closed structure or a non-closed structure surrounding the opening area by one circle.

17. (canceled)

18. The display substrate according to according to claim 1, wherein the display substrate further comprises:
a top electrode layer arranged at one side of the common transport layer away from the base substrate;
wherein the top electrode layer in the at least two adjacent opening areas and the top electrode layer on the pixel defining layer between the at least two adjacent opening areas are at least partially lapped.

19. A display device, comprising the display substrate according to claim 1.

20. A manufacturing method of a display substrate, comprising:
providing a base substrate;
forming a pixel defining layer at one side of the base substrate, the pixel defining layer being configured for defining a plurality of opening areas, and the opening area being configured for arranging a light emitting device; and
forming a common transport layer at one side of the pixel defining layer away from the base substrate;
wherein a surface of one side away from the base substrate of the pixel defining layer between at least two adjacent opening areas is covered by the common transport layer, and at least part of a side face of the pixel defining layer facing at least one opening area is not covered by the common transport layer; and
orthographic projections of the common transport layers in the at least two adjacent opening areas on the base substrate and orthographic projections of the common transport layers on the pixel defining layers between the at least two adjacent opening areas on the base substrate are continuous.

21. The manufacturing method according to claim 20, wherein the pixel defining layer comprises a partition structure, the partition structure comprises a partition groove arranged in a side face of the pixel defining layer facing the opening area, and the step of forming the pixel defining layer at one side of the base substrate comprises:
forming a bottom electrode layer at one side of the base substrate, the bottom electrode layer comprising a plurality of bottom electrodes, and orthographic projections of the plurality of bottom electrodes on the base substrate covering orthographic projections of the plurality of opening areas on the base substrate;
forming a partition material layer at one side of the bottom electrode layer away from the base substrate by patterning, an orthographic projection of the partition material layer on the base substrate covering the orthographic projections of the plurality of bottom electrodes on the base substrate;
forming the pixel defining layer at one side of the partition material layer away from the base substrate; and
etching the partition material layer located in the opening area to form a partition layer; wherein
an orthographic projection of the partition layer on the base substrate is located within an orthographic projection range of the pixel defining layer on the base substrate; and the partition layer is provided with a first end face facing the opening area, the pixel defining layer located at one side of the partition layer away from the base substrate is provided with a second end face facing the opening area, the first end face retracts in a direction away from the opening area relative to the second end face, and the first end face forms a groove bottom of the partition groove.
